(19) United States
(12) Patent Application Publication
(10) Pub. No.: US 2007/0268905 A1
(43) Pub. Date: Nov. 22, 2007

(54) Non-volatile memory error correction system and method

(75) Inventors: David Cureton Baker, Austin, TX (US); Richard Sanders, Hutto, TX (US)

Correspondence Address: DANIEL G. GABRIEL, 270 GULF ROAD, DOVER, NH, 03820, US

(73) Assignee: SIGMATEL, INC., Austin, TX (US)

(21) Appl. No.: 11/436,937

(22) Filed: May 18, 2006

(51) Int. Cl. H04L 12/56

(52) U.S. Cl. 370/392; 370/252

(57) ABSTRACT

A non-volatile memory has a first payload data region and a first redundant memory area associated with the first payload data region. The first redundant memory area has a first portion, a second portion and a third portion. The first portion includes first payload error correction code (ECC) data associated with the first payload data region. The second portion includes first metadata associated with the first payload data region. The third portion includes first metadata ECC data associated with the first metadata.

### BACKGROUND

1. Field of the Disclosure

The present disclosure is generally related to memory systems, and more particularly to non-volatile memory systems with error correction.

2. Description of the Related Art

Consumer electronic devices, such as cellular telephones, digital music players, thumb drives and other handheld devices, execute increasingly complicated algorithms, such as algorithms for decoding compressed digital audio and video data and algorithms for displaying user interfaces. As the complexity of these algorithms increases, the size of the memory for storing such algorithms also increases.

Increasingly, manufacturers are turning to non-volatile memory devices, such as flash memory devices including NAND flash and NOR flash memory devices. Typically, non-volatile memory devices store data in logical units, such as memory pages and memory blocks. Often, data is written to a particular page and may be read from locations within that page. Generally, a block is the smallest unit of data that may be erased.

In a typical flash memory device, each page has a payload data area and a redundant memory area, sometimes referred to as an overhead area or metadata area. The redundant memory area of the page stores information about the page, information about data within the page, and data associated with error correction procedures for the page.

Accessing and storing data on non-volatile memory devices, such as flash memory, typically utilizes virtual addressing. Non-volatile memory devices tend to wear with use and, as such, sectors within a solid-state non-volatile memory device may lose the capacity to store error free data. The cataloging of bad sectors and creation of sector maps is typically performed by reading a data sector and checking for particular code values in the system data. Generally, an error correction code (ECC) associated with the data of a data sector is included in a redundant data area for use in correcting noise in the data. For example, when data is to be written to the memory, an ECC is calculated based on the data to be written, and the ECC is stored with the data (e.g. in a redundant data area) in the memory. When the data is accessed, a new ECC is calculated from the accessed data and the calculated ECC is compared to the ECC stored with the data. If there is a difference between the calculated ECC and the stored ECC, the data is likely corrupted and the sector may be bad. In many examples, ECCs may be used to correct the data before transmission to subsequent memory systems or processors.

While the ECC methods may address memory errors, the process of reading ECC data in a non-volatile memory and performing error correction on corrupted data is a time consuming process. As such, there is a need for an improved error correction system and method for non-volatile memory.

### SUMMARY

In one embodiment, a non-volatile memory has a first payload data region and a first redundant memory area associated with the first payload data region. The first redundant memory area has a first portion, a second portion and a third portion. The first portion includes first payload error correction code (ECC) data associated with the first payload data region. The second portion includes first metadata associated with the first payload data region. The third portion includes first metadata ECC data associated with the first metadata.

In another embodiment, a system has a non-volatile memory and an error correction module. The non-volatile memory has payload error correction code (ECC) data associated with a payload data region and metadata ECC data that is associated with the payload data region. The error correction module includes logic to perform error correction in response to receiving the metadata ECC data.

In another embodiment, a data protection code related to a data payload is generated. A metadata protection code is generated that is related to the data protection code. The data payload is stored in a payload data region of a non-volatile memory and the data protection code and the metadata protection code are stored in a redundant data region of the non-volatile memory.

### BRIEF DESCRIPTION OF THE DRAWINGS

The present disclosure may be better understood, and its numerous features and advantages made apparent to those skilled in the art by referencing the accompanying drawings.

FIG. 1 is a block diagram of a portion of a particular illustrative embodiment of a processing system.

FIG. 2 is a block diagram of a partitioned non-volatile memory for use with a processing system, such as the system of FIG. 1.

FIG. 3 is a general diagram illustrating selected contents of a redundant memory area portion of the non-volatile memory of FIG. 2.

FIG. 4 is a block diagram of a particular embodiment of an error correction module for use with a processing system, such as the system of FIG. 1.

FIG. 5 is a block diagram of a particular embodiment of an error correction module and a general purpose memory interface module for use with a processing system, such as the system of FIG. 1.

FIG. 6 is a flow diagram of a method of writing data to a non-volatile memory.

FIG. 7 is a flow diagram of a method of reading data from a non-volatile memory.

The use of the same reference symbols in different drawings indicates similar or identical items.

### DESCRIPTION OF THE DRAWINGS

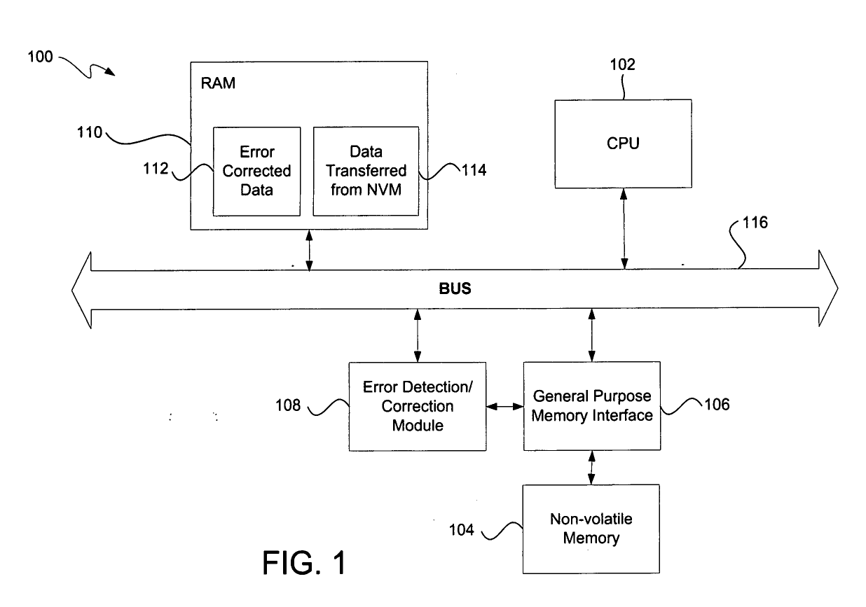

FIG. 1 is a block diagram of a portion of a particular illustrative processing system 100. The system 100 includes a central processing unit (CPU) 102, a non-volatile memory 104, a general purpose memory interface (GPMI) 106, an error detection/correction module 108, and a volatile memory, such as a cache or random access memory (RAM) 110. Error corrected data 112 and transferred data 114 from the non-volatile memory 104 may be stored in the RAM 110. The CPU 102, the non-volatile memory 104, the GPMI 106, the error detection/correction module 108, and the RAM 110 are communicatively coupled via a communications bus 116.

In general, the CPU 102 processes computer readable instructions, such as software programs. During operation, the CPU 102 generates memory access requests to the RAM 110 and to the non-volatile memory 104 to request access to particular data. The GPMI 106 may receive the memory access requests, retrieve the requested payload data, and provide the payload data and the associated error detection code and error correction code (ECC) data to the error detection/correction module 108. The error detection/correction module 108 may process the payload data to identify locations and values of errors within the payload data. The error detection/correction module 108 may correct the errors based on the identified locations and values and may store the error corrected data 112 in the RAM 110. Depending on the implementation, the GPMI 106 may transfer the requested data via the bus 116 for storage in RAM 110. The error detection/correction module 108 may load the transferred data 114 from the RAM 110 for processing based on error detection and ECC data provided by the GPMI 106.

In general, the non-volatile memory 104 may be partitioned into a data payload region and a redundant data region. Payload data may be stored in the data payload region, and error detection and error correction data associated with the payload data may be stored in the redundant data region. Additionally, metadata error correction data related to the error detection and error correction data may be stored in the redundant data region or may be stored within a metadata redundant data region, depending on the specific implementation.

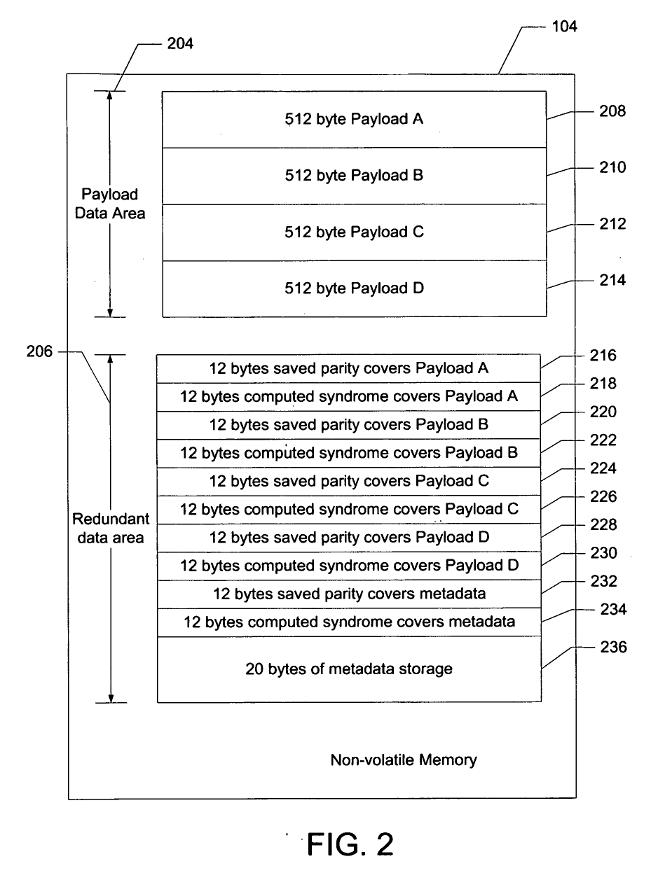

FIG. 2 illustrates a partitioned non-volatile memory 104 for use with a processing system, such as the processing system of FIG. 1. The non-volatile memory 104 is partitioned to form a payload data area 204 and a redundant data area 206. The payload data area 204 includes representative payload areas 208, 210, 212 and 214. In a particular embodiment, each of the payload areas 208-214 may contain up to 512 bytes of payload data.

The redundant data area 206 includes redundant data associated with each of the individual payload areas 208, 210, 212 and 214. The redundant data area 206 as shown includes parity areas 216, 220, 224, 228 and 232 and syndrome areas 218, 222, 226, and 230. In a particular embodiment, each of the parity areas 216, 220, 224, 228 and 232 and each of the syndrome areas 218, 222, 226, and 230 include up to 12 bytes of information related to payload data of one of the payload areas 208, 210, 212, and 214.

For example, the payload area 208 includes 512 bytes of payload data. The parity area 216 and the syndrome area 218 each include 12 bytes of parity data and 12 bytes of syndrome data, respectively. The 12 bytes of parity data and the 12 bytes of syndrome data are associated with the 512 bytes of payload data of the payload area 208. In a particular example, the parity areas 216, 220, 224, 228 and 232 each include eight 9-bit symbols with three additional bytes of alignment padding. The syndrome areas 218, 222, 226, 230 and 234 each include eight 9-bit symbols with three additional bytes of alignment padding.

In general, the metadata parity data stored in parity area 232 and the computed metadata syndrome data stored in syndrome area 234 are associated with the parity data of the of the parity areas 216, 220, 224, and 228 and with the syndrome data of the syndrome areas 218, 222, 226, and 230, respectively. Additionally, the redundant data area 206 includes 20 bytes of auxiliary storage 236. The metadata parity data and the metadata syndrome data represent parity data and syndrome data of the data stored in the parity areas 216, 220, 224, and 228 and in the syndrome areas 218, 222, 226, and 230. In one embodiment, the parity data and the syndrome data represent metadata of the payload data. The data stored in the parity area 232 and in the syndrome area 234 represent metadata of the metadata.

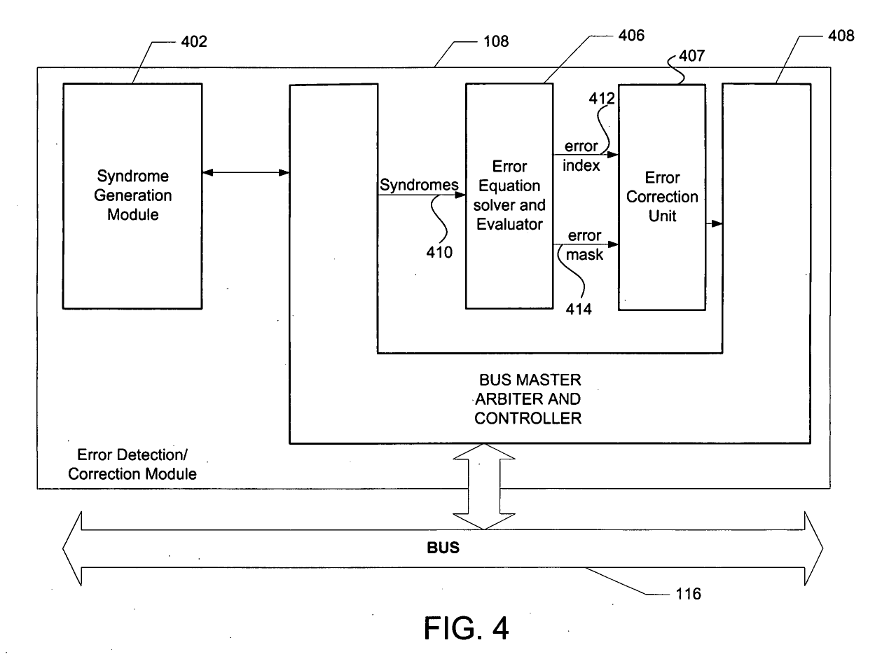

In general, the partitions and payload areas 204 and 206 of the non-volatile memory 104 of FIG. 2 illustrate a system memory footprint for a representative 2K page. The data from a syndrome generation module (shown in FIG. 4) of the error detection/correction module 108 includes 32 bits of information that is saved in the syndrome area 234 and in the auxiliary storage 236.

In an alternative embodiment, the partitions and payload areas may be adjusted for a 4K page size. For example, the data payload area 204 may be extended to include eight payload areas, each having approximately 512 bytes of information. Each of the parity areas 216, 220, 224, and 228 and each of the syndrome areas 218, 222, 226 and 230 in the redundant data area 206 may similarly be extended to store 20 bytes of parity data and 20 bytes of syndrome data. In this instance, the parity data area 232 and the syndrome data area 234 may include 12 bytes of parity and syndrome data associated with the parity areas 216, 220, 224, and 228 and with the syndrome areas 218, 222, 226, and 230, but the auxiliary data in the auxiliary data area 236 may be increased. In one instance, the auxiliary data is increased to approximately 68 bytes of information. The payload parity/syndrome areas may thus consist of sixteen 9-bit symbols with two bytes of alignment padding, and the auxiliary parity/syndrome area 236 may consist of eight 9-bit symbols with three bytes of alignment padding. In another embodiment, the metadata ECC data may be stored in a separate data area.

In another embodiment, the redundant data area 206 and the payload data area 204 may be distributed. In this instance, the parity areas 216, 220, 224, and 228 and the syndrome areas 218, 222, 226 and 230 may be at non-contiguous memory address locations. For example, the payload data of the payload data area 204 may be stored in separate payload partitions at various memory addresses, which may be interspersed with redundant data partitions of the redundant data area 206. For example, the payload area 208, the associated parity area 216, and the syndrome area 218 may be stored in adjacent memory partitions within the non-volatile memory 104.

In general, the parity and syndrome data provide information that can be used by the error detection/correction module 108 to detect and correct data errors within the payload data. Moreover, if the parity/syndrome data includes errors, the metadata ECC data may be used by the error detection/correction module 108 to detect and correct such errors.

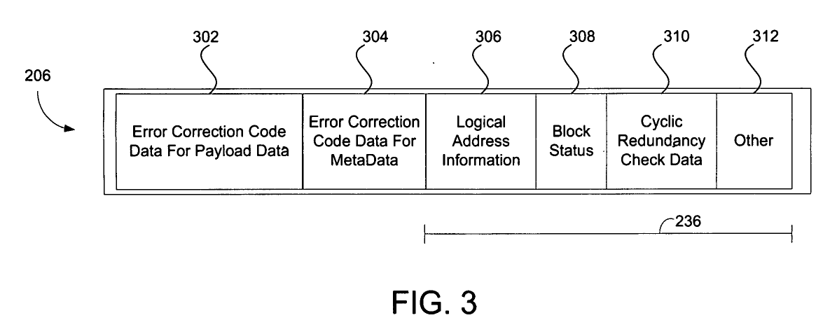

FIG. 3 illustrates selected contents of a portion of the redundant memory area 206 of the non-volatile memory 104. In general, the redundant memory area 206 includes error correction data 302, which may include thee payload parity data and the payload syndrome data, as shown in FIG. 2. Additionally, the redundant memory area 206 includes error correction code (ECC) data 304, which may include metadata parity data and metadata syndrome data. Additionally, the redundant memory area 206 may include logical address information 306, data block status information 308, cyclic redundancy check (CRC) data 310, and other data 312 associated with the metadata.

In general, the payload data is stored in a payload data area of the non-volatile memory and the redundancy data associated with the payload data is stored in a redundant data area of the non-volatile memory. The redundancy data includes a first payload error correction code (ECC) data associated with a first payload data region, and a first metadata associated with the first payload data region. A metadata ECC data associated with the first metadata may also be stored in the redundant data area. The metadata ECC data may be retrieved and used to correct errors in the redundancy data, without having to retrieve the payload data from memory. The first metadata may include cyclic redundancy check (CRC) data, or other types of error detection data. Alternatively, the first metadata may include an error syndrome, which can be used by an error correction module to correct an error in payload data or in metadata associated with the payload data.

FIG. 4 is a block diagram of a particular embodiment of the error detection/correction module 108 for use with a processing system, such as the system 100 of FIG. 1. The error detection/correction module 108 includes a syndrome generation module 402, an error equation solver and evaluator 406, an error correction unit 407, and an AHB bus master arbiter and controller 408. The AHB bus master arbiter and controller 408 performs a weighted hierarchical arbitration for access requests for syndrome retrieving and error correction.

In general, the AHB bus master arbiter and controller 408 couples the error detection/correction module 108 to the bus 116 for communication with other modules and components of the system 100. In general, the AHB bus master arbiter and controller 408 provides high bandwidth and low latency for data transactions by performing burst operations, fixed priority arbitration and the like. Moreover, the AHB bus master arbiter and controller 408 limits stalls from the NAND interface (the GPMI 106.

In general, the syndrome generation module 402 receives blocks of data from the non-volatile memory 104 via the general purpose memory interface (GPMI) 106. The blocks of data may include a fixed amount of payload data and parity data associated with the fixed amount of payload data. The syndrome generation module 402 may also receive control information associated with a data block. The syndrome generation module 402 calculates syndrome information from the payload and parity data. The syndrome generation module 402 provides the payload data, the parity data and the calculated syndromes to the bus master arbiter and controller 408.

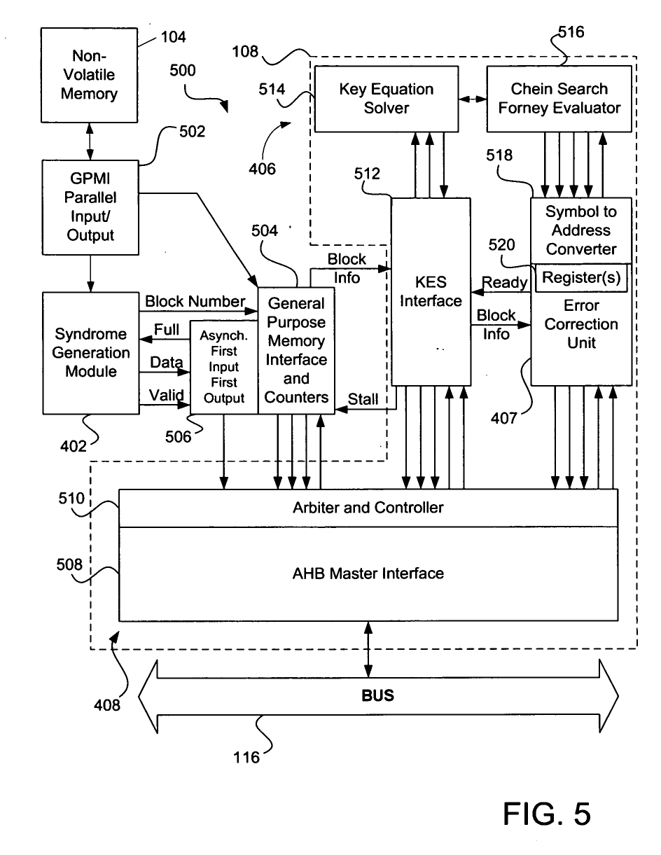

The bus master arbiter and controller 408 may include an asynchronous first input first output (FIFO) register (as shown in FIG. 5) to receive the payload data, the parity data, the calculated syndrome information, and the control information. Moreover, the bus master arbiter 408 may provide a flow control signal to the syndrome generation module 402, when the FIFO register is full.

Alternatively, the syndrome generation module 402 may store the payload data, the parity data, the syndrome information and the control information in a system memory or another memory location, such as RAM 110 in FIG. 1, until the bus master arbiter and controller 408 and the error equation solver and evaluator 406 are available for error processing.

The error equation solver and evaluator 406 receives the syndromes 410 of the payload data from the bus master arbiter and controller 408. The error equation solver and evaluator 406 processes the syndromes 410 to produce a symbol index 412 and a symbol mask 414. The symbol index 412 identifies symbols that contain one or more errors, and the symbol mask 414 indicates the particular bits within the symbol which should be complemented to correct the error. The error equation solver and evaluator 406 notifies the bus master arbiter and controller 408 when processing is complete so that the bus master arbiter and controller 408 can present the next set of syndromes 410. The error equation solver and evaluator 406 provides pairs of error indexes 412 and masks 414 to the error correction unit 407, which complements the particular bit errors via the bus master arbiter and controller 408. The error equation solver and evaluator 406 may also provide an indication of how many corrections were required or an indication that the payload data was uncorrectable to the bus master arbiter and controller 408.

In general, if the syndrome generation module 402 marks a block of data as containing errors, then the bus master arbiter and controller 408 schedules an error correction pass through the key equation solver. Thus, the syndrome generation module 402 performs an error detection on blocks of data, and the error correction process is performed by the error equation solver and evaluator 406 only when errors are detected.

The bus master arbiter and controller 408 may be adapted to complement data bits within a block of memory using the error index and the error mask. The corrected data may be stored in a system memory, in a temporary memory such as a cache memory or the RAM memory 110, in a non-volatile memory, such as the non-volatile memory 104, and/or in any combination thereof.

In general, the error equation solver and evaluator 406 can provide an error index 412 and an error mask 414 for a correctable block of data, where a block of data includes n-symbols minus 2t-parity symbols. The n-symbols refers to a block size in symbols (such as 512 symbols in the payload data areas of FIG. 2, for example), and the symbol (t) refers to the number of correctable errors. In one embodiment, the number of correctable errors within a 512 byte block may be 4 errors. In another embodiment, the number of correctable errors within a 512 byte block may be 8 errors. Depending on the error correction calculations used, greater or fewer numbers of errors may be correctable.

The syndrome generation module 402 calculates 2t syndromes. The error equation solver and evaluator 406 generates a set of 2t linear equations with 2t unknown variables. The error equation solver and evaluator 406 solves the set of equations using an Euclidean algorithm, which divides a special polynomial of degree 2*t (e.g. x⁸ or x¹⁶) by the syndrome polynomial formed from the 2t syndromes. Once the division generates a remainder of degree that is less than or equal to the number of correctable errors (t), the error equation solver and evaluator 406 terminates the algorithm and creates an error evaluator polynomial and an error locator polynomial to determine the error index 412 and the error mask 414.

FIG. 5 is a block diagram of an embodiment of an error correction system 500 having an error correction module and a general purpose memory interface (GPMI) module for use with a processing system, such as the system 100 of FIG. 1. The system 500 includes a general purpose memory interface (GPMI) parallel input/output 502, a syndrome generator 402, an error correction module 108, a bus master arbiter and controller 408, a general purpose memory interface and counters 504, an asynchronous first input first output (FIFO) register 506, and a bus 116. The GPMI parallel input/output 502 is communicatively coupled to the GPMI and counters 504 and to the syndrome generator 402. Additionally, the GPMI parallel input/output 502 may be coupled to the non-volatile memory 104.

The syndrome generator 402 is coupled to the asynchronous FIFO 506 and to the GPMI and counters 504. The asynchronous FIFO 506 is also connected to the GPMI and counters 504 and to the bus master arbiter and controller 408. The GPMI and counters 504 is connected to the bus master arbiter and controller 408 and to the error correction module 108.

The error correction module 108 includes a key equation solver (KES) interface 512, a key equation solver 514, a Chein search and Forney evaluator 516, a symbol to address converter 518, one or more registers 520, and an error correction module 522. The KES interface 512 is coupled to the bus master arbiter and controller 408, to the key equation solver 514, and to the error correction module 522. The Chein search/Forney Evaluator 516 is connected to the symbol to address converter 518, which may be connected to one or more registers 520 and to the error correction module 522. The error correction module 522 is connected to the bus master arbiter and controller 408.

The bus master arbiter and controller 408 includes a bus master interface 508 and an arbiter and controller 510. The bus master interface 508 is connected to the bus 116, and the arbiter and controller 510 is connected to the GPMI and counters 504, to the asynchronous FIFO 506, to the KES interface 512, and to the error correction module 522.

In general, the GPMI parallel Input/output 502 provides address information to the GPMI and counters 504. The syndrome generation module 402 provides a block number to the GPMI and counters 504. Additionally, the syndrome generation module 402 provides payload data blocks to the asynchronous FIFO 506 along with calculated syndrome data, parity data, and control information. On read operations, the payload data blocks are processed by the syndrome generation module 402 and passed to the asynchronous FIFO 506. In one particular implementation, except for the last write operation, the output word of the syndrome generation module 402 consists of 32-bits of data (meaning either payload, parity or syndrome bits) and 4 flag bits. The last output word of a payload data block may be a status word that identifies whether certain conditions were detected within the block that might save processing time. For example, if the symbol generation module 402 did not detect an error, error correction may be avoided. The asynchronous FIFO 506 may provide a flow control signal to the syndrome generation module 402 to control the transfer of the data blocks and syndrome information. The data block and associated parity and syndromes information may be written to the asynchronous FIFO 506.

In addition, there are a number of control signals that pass from the GPMI and counters 504 and from the syndrome generation module 402 to the bus master arbiter and controller 408, such as a mode bit, memory addresses, a channel number, and the like. Typically, the control information may be included at the beginning of a payload data block.

The asynchronous FIFO 506 provides the data, syndrome information, parity data, and control information to the GPMI and counters 504. In general, the control information may include bit flags that indicate the first word of a new data block, the start and end of a data block transfer, and a status word flag. Control logic of the asynchronous FIFO 506 may monitor the status of the FIFO and report a full condition to the syndrome generation module 402 whenever the FIFO has insufficient space for new data.

The GPMI and counters 504 transfers the data and syndrome information to the KES interface 512. The KES interface 512 provides the calculated syndrome data to the key equation solver 514 for error detection. If a block of data is marked with no error, the GPMI and counters 504 may transfer the block of data to the arbiter and controller 510, bypassing the KES interface 512. The key equation solver 514 provides error detection information to the Chein search and Forney Evaluator unit 516.

Once the key equation solver 514 has completed the error detection, the KES interface 512 provides the block information to the error correction module 522. The Chein search and Forney evaluator (CF) unit 516 calculates error masks and error indices for the data block and provides them to the error correction unit 522. The symbol to address converter 518 converts the symbol index into a system word-aligned address and converts the symbol mask into a word-aligned mask.

The error correction module 522 performs a word read-modify-write operation to complete an error correction. Depending on the operating mode of the system, the number of read-write-modify corrections may vary. For example, there may be up to 16 read-modify-write corrections for an 8-bit mode, and up to 8 read-modify-write corrections for a 4-bit mode.

It should be understood that while the above discussion focused on a generic read operation, the error correction may be applied in a number of ways. For example, changes to payload data may also require changes to the metadata and to the metadata ECC data stored in the redundant data area of the non-volatile memory. Errors detected in the payload data may be corrected using the metadata. Errors in the metadata may be corrected using the metadata ECC data. The recovery process may be applied to the payload data, to the payload error detection data (such as parity data), to metadata, to metadata ECC data, and so on. By storing the metadata, the parity data, the metadata error correction code (ECC) data, and the payload data separately, the error correction module 108 can access one or more of the data elements to efficiently correct data errors.

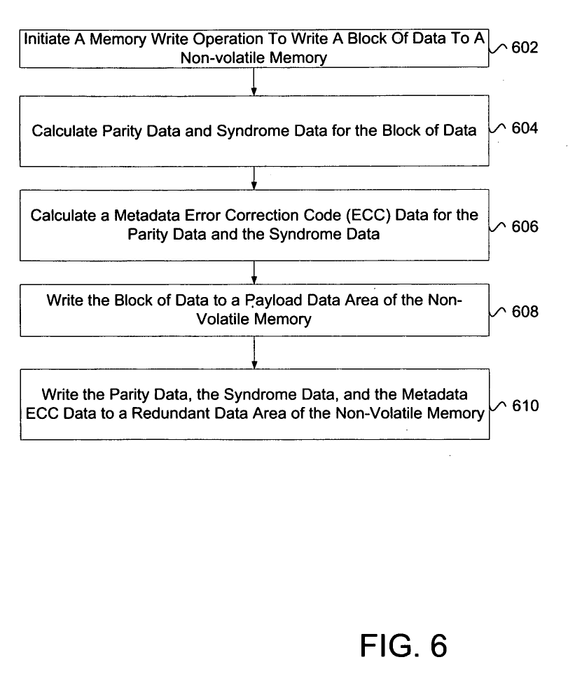

FIG. 6 is a flow diagram of a method of writing data to a non-volatile memory. A memory write operation is initiated for writing a block of data to the non-volatile memory (block 602). Parity data and syndrome data for the block of data are calculated (block 604). Metadata error correction code (ECC) data is calculated for the parity data and the syndrome data (block 606). The block of data is written to a payload data area of the non-volatile memory (block 608). The parity data, the syndrome data, and the metadata ECC data are written to a redundant data area of the non-volatile memory (block 610).

In general, each write operation causes the error correction module to generate the syndrome data based on the payload data (e.g. metadata) and to generate metadata ECC data based on the syndrome data. During an error correction process, the metadata ECC data may be used by the error correction module to correct the syndrome data, and the syndrome data may be used to correct the payload data. These error correction processes may be performed sequentially or independently from one another.

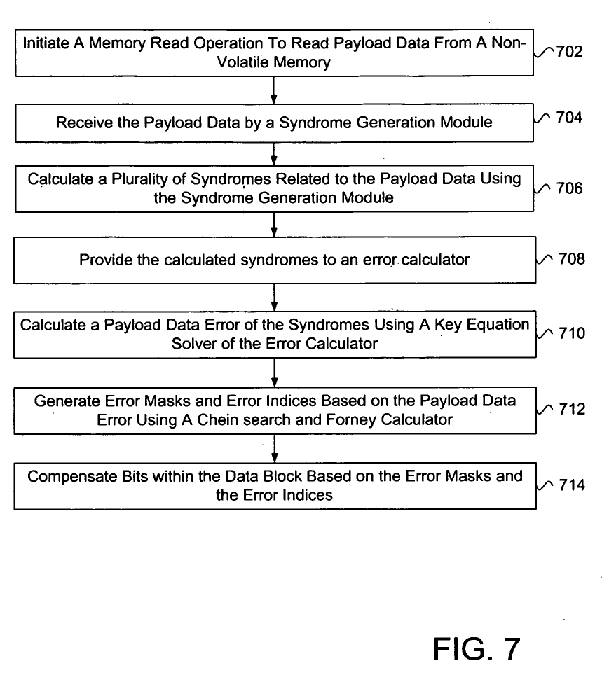

FIG. 7 is a flow diagram of a method of reading payload data from a non-volatile memory. A memory read operation is initiated to read payload data from a non-volatile memory (block 702). The payload data is received by a syndrome generation module (block 704). The syndrome generation module calculates a plurality of syndromes related to the payload data (block 706). The syndrome generation module provides the calculated syndromes to an error calculator (block 708). A key equation solver of the error calculator calculates a payload data error from the syndromes (block 710). A Chein search and Forney calculator of the error calculator generates error masks and error indices based on the payload data error (block 712). An error correction module of the error calculator compensates bits within the data block based on the error masks and error indices (block 714).

In general, the reading of payload data from the non-volatile memory may proceed as described with respect to FIG. 7. Alternatively, if an error is detected in payload parity data or payload metadata stored within the redundant data area of the non-volatile memory, the error correction module retrieves the metadata error correction code (ECC) data associated with the payload metadata. The metadata ECC data is then used to calculate a plurality of syndromes (as in block 706) above, related to the payload metadata. The key equation solver calculates a payload metadata error from the syndromes. The Chein search and Forney calculator generates error masks and error indices based on the payload metadata error. The error correction module compensates bits within the payload metadata based on the error masks and error indices. Thus, the metadata of payload data may be recovered from the metadata ECC data stored in the redundant data area without also loading the payload data, thereby saving time and computing resources.

By storing the metadata and error detection data in a redundant data area of the non-volatile memory and by storing metadata error correction code (ECC) data associated with the metadata and the error detection data separately within the redundant data area, logic within the error correction module may correct for bit errors in the payload data and within the metadata of the payload data, without having also to load the payload data.

The metadata ECC data may include a syndrome associated with the metadata of payload data. The non-volatile memory may include payload ECC data as well as metadata ECC data. Each data payload within the data payload area may have a corresponding parity data area and syndrome data area within the redundant data area. Each corresponding parity data area and syndrome data area pair may have a corresponding metadata ECC data stored within the redundant data area. Thus, a first data payload may have first parity data and first metadata, which are stored in a redundant data area. The first parity data and the first metadata may have corresponding first metadata ECC data. A second data payload may have a second parity data and a second metadata, which are stored in a redundant data area. In one embodiment, the first metadata ECC data includes metadata ECC data for the first and the second parity data and the first and the second metadata. In a second embodiment, second metadata ECC data includes metadata ECC data for the second parity data and the second metadata.

The above-disclosed subject matter is to be considered illustrative, and not restrictive, and the appended claims are intended to cover all such modifications, enhancements, and other embodiments that fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A non-volatile memory comprising:
a first payload data region;
a first redundant memory area associated with the first payload data region, the first redundant memory area comprising:
a first portion including first payload error correction code (ECC) data associated with the first payload data region;
a second portion including first metadata associated with the first payload data region; and
a third portion including first metadata ECC data associated with the first metadata.

2. The non-volatile memory of claim 1, further comprising:
a second payload data region; and
wherein the first metadata is associated with the first payload data region and the second payload data region.

3. The non-volatile memory of claim 2, wherein the first redundant memory area includes second payload error correction code (ECC) data associated with the second payload data region.

4. The non-volatile memory of claim 1, wherein the first payload error correction code (ECC) data includes parity data and syndrome data.

5. The non-volatile memory of claim 1, wherein the first payload data region comprises a memory space of 512 bytes.

6. The non-volatile memory of claim 1, wherein the first metadata includes cyclic redundancy check (CRC) data.

7. The non-volatile memory of claim 1, wherein the first metadata includes block status data.

8. The non-volatile memory of claim 1, wherein the first metadata includes logical address data associated with the first payload data region.

9. The non-volatile memory of claim 1, further comprising:
a second payload region;
a second redundant memory area associated with the second payload data region, the second redundant memory area comprising:
a first portion having second payload error correction code (ECC) data associated with the second payload region;
a second portion having second metadata associated with the second payload region; and
a third portion including second metadata ECC data associated with the second metadata.

10. A system comprising:
a non-volatile memory including payload error correction code (ECC) data associated with a payload data region and metadata ECC data that is associated with the payload data region;
an error correction module including logic to perform error correction in response to receiving the metadata ECC data.

11. The system of claim 10, wherein the metadata ECC data includes an error syndrome, and wherein the error correction module includes a syndrome generation module to generate the error syndrome.

12. The system of claim 10, wherein the error correction module includes a key generation module to generate error correction information based on the error syndrome to correct an error in metadata accessed from the non-volatile memory.

13. The system of claim 12, wherein the error correction information includes an error index and an error mask.

14. The system of claim 10, wherein the non-volatile memory includes payload ECC data and metadata ECC data, each associated with a second payload data region.

15. The system of claim 12, wherein the error correction module performs Reed-Solomon error correction on the metadata.

16. A method comprising:
generating a data protection code related to a data payload;
generating a metadata protection code related to the data protection code; and
storing the data payload in a payload data region of a non-volatile memory and storing the data protection code and the metadata protection code in a redundant data region of the non-volatile memory.

17. The method of claim 16, wherein the data protection code comprises error detection data and error correction data.

18. The method of claim 17, wherein the error detection data comprises parity data.

19. The method of claim 16, wherein the data protection code comprises cyclic redundancy check (CRC) data and error correction code (ECC) data.

20. The method of claim 16, wherein the metadata protection code comprises error correction code (ECC) data related to the data protection code.

21. The method of claim 16, wherein generating the data protection code comprises calculating at least one parity data and error correction code (ECC) data for the data payload.

22. The method of claim 16, wherein generating the metadata protection code comprises calculating metadata error correction code (ECC) data.

23. A system comprising:
an error correction module having access to a non-volatile memory, the error correction module including logic to generate a plurality of syndromes associated with a block of data retrievable from the non-volatile memory, the error correction module further including logic to compensate for bit errors within the block of data and including logic to use metadata error correction code (ECC) data to correct for bit errors in metadata retrieved from the non-volatile memory.
